(19) United States
(12) Patent Application Publication
(10) Pub. No.: US 2008/0315388 A1
(43) Pub. Date: Dec. 25, 2008

(54) VERTICAL CONTROLLED SIDE CHIP CONNECTION FOR 3D PROCESSOR PACKAGE

(76) Inventors: Shanggar Periaman, Gelugor (MY); Bok Eng Cheah, Bayan Lepas (MY); Yen Hsiang Chew, Georgetown (MY); Kooi Chi Ooi, Bayan Lepas (MY)

Correspondence Address: INTEL CORPORATION;c/o INTELLEVATE, LLC, P.O. BOX 52050, MINNEAPOLIS, MN, 55402, US

(21) Appl. No.: 11/767,318

(22) Filed: Jun. 22, 2007

(51) Int. Cl. H01L 23/52; H01L 23/48

(52) U.S. Cl. 257/690; 257/777; 257/E23.141; 257/E23.01

(57) ABSTRACT

In some embodiments, vertical controlled side chip connection for 3D processor package is presented. In this regard, an apparatus is introduced having a substrate, a substantially horizontal, in relation to the substrate, integrated circuit device coupled to the substrate, and a substantially vertical, in relation of the substrate, integrated circuit device coupled to the substrate and adjacent to one side of the substantially horizontal integrated circuit device. Other embodiments are also disclosed and claimed.

### FIELD OF THE INVENTION

Embodiments of the present invention generally relate to the field of integrated circuit packaging and, more particularly, to vertical controlled side chip connection for 3D processor package.

### BACKGROUND OF THE INVENTION

Computing devices are expected to have more and more features and be available in ever smaller form factors. This raises problems such as finding space to route traces along a printed circuit board (PCB) and integrating functionality into silicon integrated circuit devices.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of an integrated circuit package with vertical controlled side chip connections, in accordance with one example embodiment of the invention;

FIG. 2 is a graphical illustration of a cross-sectional view of an alternate integrated circuit package with vertical controlled side chip connections, in accordance with one example embodiment of the invention;

FIG. 3 is a graphical illustration of an overhead view of an alternate integrated circuit package with vertical controlled side chip connections, in accordance with one example embodiment of the invention; and

FIG. 4 is a block diagram of an example electronic appliance suitable for implementing vertical controlled side chip connection for 3D processor package, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of an integrated circuit package with vertical controlled side chip connections, in accordance with one example embodiment of the invention. As shown, integrated circuit package 100 includes one or more of vertical chip stack 102, main chip stack 104, vertical chip 106, substrate 108, vertical substrate 110, vertical chips 112-116, surface activated bond 118, die backside metallization (DBM) connection 120, die active metal layer 122, DBM routing and/or pad 124, through silicon via (TSV) 126, wirebond 128, underfill and solder bump connection 130, and DBM surface activated bond 132.

Vertical chip stack 102 represents a group of integrated circuit devices, for example multi-core microprocessors, flash memory, network controllers, graphics controllers, etc., which are connected to and vertically aligned in relation with substrate 108. Vertical chip stack 102 may be fabricated separately with vertical chips 112-116 coupled with vertical substrate 110 through conventional methods before being rotated and placed on substrate 108. Vertical chip stack 102 may be coupled (electrically as well as mechanically) with substrate 108 and/or main chip stack 104. In one embodiment, a surface activated bond 118 is formed between conductive surfaces on vertical substrate 110 and substrate 108. In one embodiment, die backside metallization (DBM) connection 120 couples vertical chips 112 and 114. DBM routing and/or pad 124 is coupled to die active metal layer 122 through through silicon via (TSV) 126. In one embodiment, vertical chip stack 102 is electrically coupled with main chip stack 104 through wirebond 128. The electrical connection between vertical chip stack 102 and main chip stack 104 may be used for power or data transmission.

Main chip stack 104 represents horizontally stacked integrated circuit devices of all types.

Substrate 108 provides mechanical support and signal routing for attached integrated circuit devices. In one embodiment substrate 108 is a multi-layer organic substrate. In another embodiment, substrate 108 is a ceramic substrate.

Vertical chip 106 may be coupled with substrate 108 through solder bump connection 130 with or without underfill support and by main chip stack 104 through any electrical interconnection including but not limited to DBM surface activated bond 132.

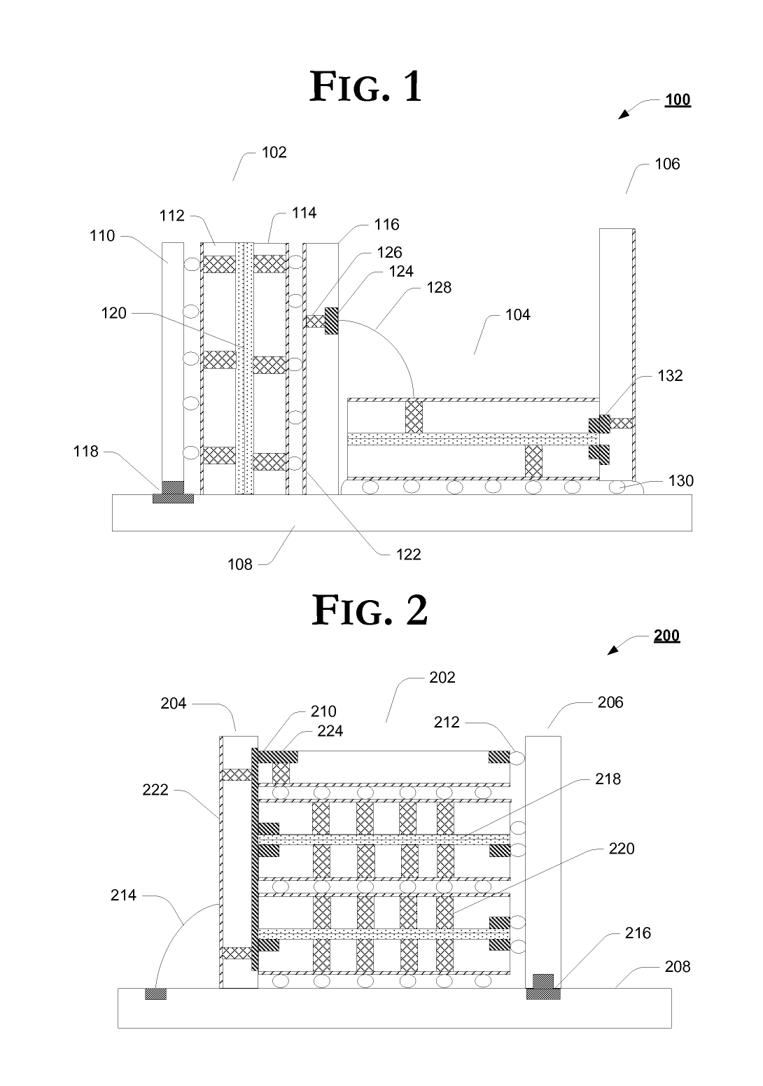

FIG. 2 is a graphical illustration of a cross-sectional view of an alternate integrated circuit package with vertical controlled side chip connections, in accordance with one example embodiment of the invention. As shown, integrated circuit package 200 includes one or more of main die stack 202, vertical die 204, vertical die 206, substrate 208, DBM surface activated bond 210, solder bump connections 212, wirebond 214, surface activated bond 216, die backside metallization (DBM) connection 218, through silicon via (TSV) connection 220, die active metal layer 222 and DBM routing and/or pad 224.

Main die stack 202 is comprised of horizontally stacked integrated circuit devices joined by multiple connections. Some chips in main die stack 202 are connected through die backside metallization (DBM), such as die backside metallization (DBM) connection 218. Die active metal layer 222 is connected to the DBM routing and/or pad through through silicon via (TSV) 220.

Vertical die 204 is coupled with main die stack 202 through surface activated bond 210 and is coupled with substrate 208 through wirebond 214.

Vertical die 206 is coupled with main die stack 202 through interconnection between solder bump connections 212 and DBM routing and/or pad 224. Vertical die 206 is coupled with substrate 208 through surface activated bond 216.

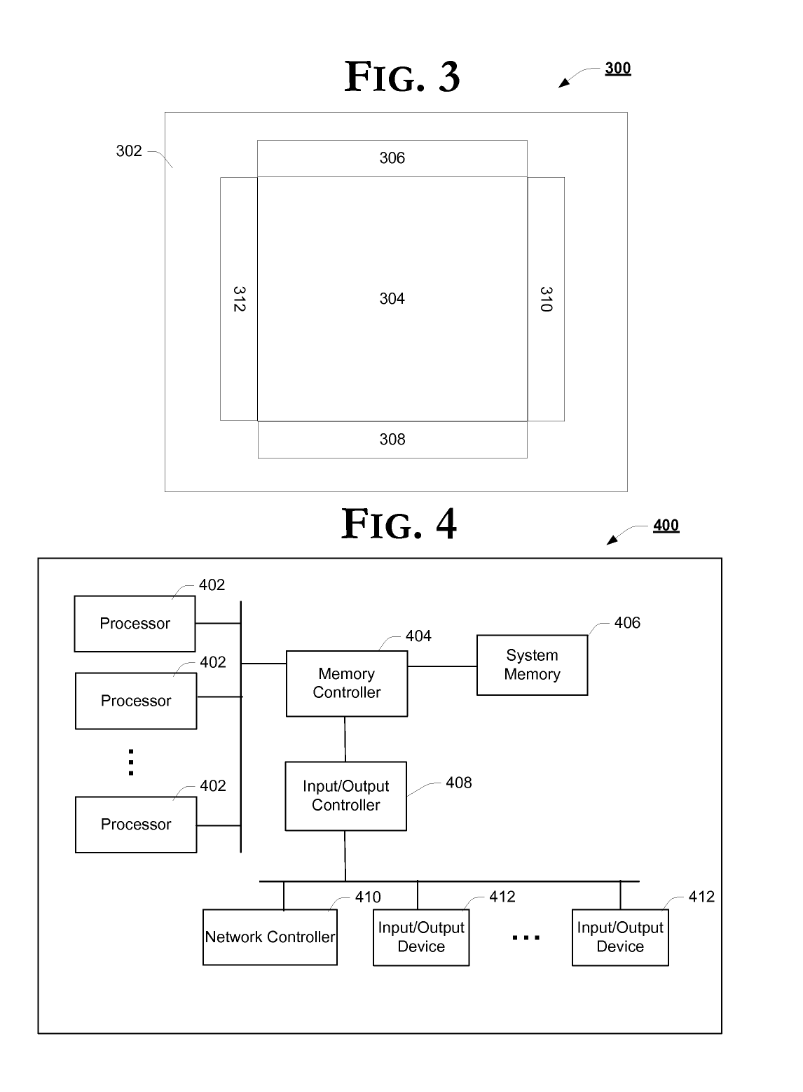

FIG. 3 is a graphical illustration of an overhead view of an alternate integrated circuit package with vertical controlled side chip connections, in accordance with one example embodiment of the invention. As shown, integrated circuit package 300 includes substrate 302, main die stack 304 and vertical devices 306-312. While connections are not shown in FIG. 3 for simplicity, main die stack 304 includes any number of integrated circuit devices horizontally stacked on substrate 302. Vertical devices 306-312 are vertically adjacent to all four sides of main die stack 304. Vertical devices 306-312 may have electrical and/or mechanical connections to substrate 302 and/or main die stack 304.

FIG. 4 is a block diagram of an example electronic appliance suitable for implementing vertical controlled side chip connection for 3D processor package, in accordance with one example embodiment of the invention. Electronic appliance 400 is intended to represent any of a wide variety of traditional and non-traditional electronic appliances, laptops, desktops, servers, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 400 may include one or more of processor(s) 402, memory controller 404, system memory 406, input/output controller 408, network controller 410, and input/output device(s) 412 coupled as shown in FIG. 4. Processor(s) 402, or other integrated circuit components of electronic appliance 400, may be integrated into packages described previously as an embodiment of the present invention.

Processor(s) 402 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 402 are Intel® compatible processors. Processor(s) 402 may have an instruction set containing a plurality of machine level instructions that may be invoked, for example by an application or operating system.

Memory controller 404 may represent any type of chipset or control logic that interfaces system memory 406 with the other components of electronic appliance 400. In one embodiment, the connection between processor(s) 402 and memory controller 404 may be referred to as a front-side bus. In another embodiment, the connection between processor(s) 402 and memory controller 404 may be a serial point-to-point connection.

System memory 406 may represent any type of memory device(s) used to store data and instructions that may have been or will be used by processor(s) 402. Typically, though the invention is not limited in this respect, system memory 406 will consist of dynamic random access memory (DRAM). In one embodiment, system memory 406 may consist of Rambus DRAM (RDRAM). In another embodiment, system memory 406 may consist of double data rate synchronous DRAM (DDRSDRAM).

Input/output (I/O) controller 408 may represent any type of chipset or control logic that interfaces I/O device(s) 412 with the other components of electronic appliance 400. In one embodiment, I/O controller 408 may be referred to as a south bridge. In another embodiment, I/O controller 408 may comply with the Peripheral Component Interconnect (PCI) Express™ Base Specification, Revision 1.0a, PCI Special Interest Group, released Apr. 15, 2003.

Network controller 410 may represent any type of device that allows electronic appliance 400 to communicate with other electronic appliances or devices. In one embodiment, network controller 410 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 410 may be an Ethernet network interface card.

Input/output (I/O) device(s) 412 may represent any type of device, peripheral or component that provides input to or processes output from electronic appliance 400.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a substrate;
a substantially horizontal, in relation to the substrate, integrated circuit device coupled to the substrate; and
a substantially vertical, in relation to the substrate, integrated circuit device coupled to the substrate and adjacent to one side of the substantially horizontal integrated circuit device.

2. The apparatus of claim 1, wherein the substantially vertical integrated circuit device is coupled to the substrate through solder bumps and with or without underfill support material.

3. The apparatus of claim 1, wherein the substantially vertical integrated circuit device is coupled to the substrate through surface activated bonding.

4. The apparatus of claim 1, further comprising a second substantially vertical integrated circuit device coupled with the first substantially vertical integrated circuit device through die backside metallization contacts.

5. The apparatus of claim 4, wherein the first and second substantially vertical integrated circuit devices are coupled through through silicon vias (TSV).

6. The apparatus of claim 4, wherein the substantially vertical integrated circuit devices are coupled electrically and mechanically with the substantially horizontal integrated circuit devices.

7. The apparatus of claim 4, wherein the substantially vertical integrated circuit devices are coupled with the substantially horizontal integrated circuit devices through wirebonding.

8. The apparatus of claim 4, further comprising a second substantially vertical substrate coupled with the first and second substantially vertical integrated circuit devices.

9. An electronic appliance comprising:
a network controller;
a system memory; and
a processor, wherein the processor includes a package comprising a substrate, a stack of integrated circuit devices coupled to the substrate, and a vertically oriented integrated circuit device coupled to a side of the stack of integrated circuit devices.

10. The electronic appliance of claim 9, further comprising a second vertically oriented integrated circuit device coupled to a second side of the stack of integrated circuit devices.

11. The electronic appliance of claim 9, further comprising the vertically oriented integrated circuit device coupled to the substrate.

12. The electronic appliance of claim 9, wherein the vertically oriented integrated circuit device is coupled to the stack of integrated circuit devices through surface activated bonding.

13. The electronic appliance of claim 9, wherein the vertically oriented integrated circuit device is coupled to the stack of integrated circuit devices through solder bumps.

14. The electronic appliance of claim 9, wherein the stack of integrated circuit devices are coupled to each other through die backside metallization.

15. The electronic appliance of claim 9, wherein the stack of integrated circuit devices are coupled to each other through through silicon vias (TSV).

16. An apparatus comprising:
a substrate;
a horizontal first integrated circuit device electrically and mechanically coupled with the substrate along a main surface; and
a vertical second integrated circuit device electrically and mechanically coupled with the substrate along a side surface.

17. The apparatus of claim 16, further comprising the first and second integrated circuit devices electrically and mechanically coupled to each other.

18. The apparatus of claim 17, wherein the first and second integrated circuit devices are coupled to each other through solder bumps.

19. The apparatus of claim 17, wherein the first and second integrated circuit devices are coupled to each other through wirebonding.

20. The apparatus of claim 16, wherein the first integrated circuit device comprises a microprocessor.
